(19) United States
(12) Patent Application Publication
(10) Pub. No.: US 2015/0334259 A1
(43) Pub. Date: Nov. 19, 2015

(54) CIRCUIT BOARD, IMAGE SENSOR UNIT, IMAGE READING APPARATUS, AND IMAGE FORMING APPARATUS

(71) Applicant: CANON COMPONENTS, INC, Kodama-gun (JP)

(72) Inventor: Akio MIHARA, Saitama (JP)

(21) Appl. No.: 14/698,238

(22) Filed: Apr. 28, 2015

(30) Foreign Application Priority Data
May 16, 2014 (JP) 2014-102606

(51) Int. Cl. H04N 1/00; H05K 1/18; H05K 1/03; H04N 1/191; H05K 1/11

(52) U.S. Cl. CPC H04N 1/00557; H04N 1/191; H04N 1/00559; H05K 1/111; H05K 1/0313; H05K 1/181; H05K 2201/09418; H05K 2201/10151

(57) ABSTRACT

A circuit board includes: a printed board including SWB pads for wire bonding and lands; image sensor ICs mounted on the printed board by a thermosetting adhesive and including FWB pads for wire bonding to be electrically connected to the SWB pads by wire bonding; and surface-mount elements mounted on the lands by soldering, wherein the surface-mount elements and the lands are connected by solders including bromine-containing flux, and coating films are formed on surfaces of the solders to prevent attachment of bromine to the SWB pads and the FWB pads.

### CROSS-REFERENCE TO RELATED APPLICATIONS

This application is based upon and claims the benefit of priority of the prior Japanese Patent Application No. 2014-102606, filed on May 16, 2014, the entire contents of which are incorporated herein by reference.

### BACKGROUND OF THE INVENTION

1. Field of the Invention

The present invention relates to a circuit board, an image sensor unit, an image reading apparatus, and an image forming apparatus. For example, the present invention relates to a circuit board mixedly including elements mounted by soldering and elements mounted by using a thermosetting adhesive and electrically connected by wire bonding and relates to an image sensor unit, an image reading apparatus, and an image forming apparatus including the circuit board.

2. Description of the Related Art

Some circuit boards incorporated into various electronic devices and apparatuses mixedly include elements mounted by soldering and elements mounted by using a thermosetting adhesive and electrically connected by wire bonding. For example, Japanese Laid-open Patent Publication No. 2007-046981 discloses a configuration of using soldering to mount surface mount components, such as resistor elements and capacitor elements, and a configuration of wire bonding to electrically connect the surface mount components. In another example, soldering is used to mount chip resistors, chip capacitors, and the like on a circuit board incorporated into an image sensor unit of a scanner, and then wire bonding is used to electrically connect image sensor ICs, which have been bonded by a thermosetting adhesive, to a desired circuit.

There has been a need for reduction in the distance between elements mounted on a circuit board due to high integration of elements and downsizing of circuit boards. This requires bringing soldering lands provided on the board closer to pads arranged on the elements to be connected to a desired circuit by wire bonding. This configuration causes the following problem. The flux of the solder contains halogen bromine to improve the solderability. The bromine remaining in the solder is vaporized and diffused (scattered) during a curing process of using a thermosetting adhesive to bond, to the board, the elements to be connected to a desired circuit by wire bonding. In this case, if the soldering lands of the board and the pads for wire bonding of the elements are close to the solder, the diffused bromine is more likely to attach to the pads for wire bonding. As a result, when, for example, an alloy of aluminum and gold is formed at the bonding parts of the pads for wire bonding and bonding wires after the wire bonding, the corrosion may progress with time due to the attached bromine, which may cause poor bonding.

### SUMMARY OF THE INVENTION

In view of the circumstances, an object of the present invention is to prevent corrosion of bonding parts of pads and wires caused by attachment of bromine in a circuit board including elements mounted by soldering and elements to be connected to a desired circuit by wire bonding.

To solve the problem, the present invention provides a circuit board including: a printed board including board side pads for wire bonding and soldering lands; first elements mounted on the printed board by a thermosetting adhesive and including element side pads for wire bonding to be electrically connected to the board side pads by wire bonding; and second elements to be mounted on the lands by soldering, wherein the second elements and the lands are connected by solders including bromine-containing flux, and coating films are formed on surfaces of the solders to prevent attachment of bromine to the board side pads and the element side pads.

### BRIEF DESCRIPTION OF THE DRAWINGS

FIG. 1 is an external perspective view, extracting and enlarging part of a circuit board, and is an enlarged view of a section I of FIG. 2;

FIG. 2 is a schematic external perspective view of an example of a configuration of the circuit board;

FIG. 3 is a sectional arrow view of a line III-III of FIG. 1 and is a schematic sectional view of an example of a configuration of the circuit board;

FIG. 4A is a schematic plan view of an example of a configuration of coating films;

FIG. 4B is a schematic plan view of an example of the configuration of the coating films;

FIG. 4C is a schematic plan view of an example of the configuration of the coating films;

FIG. 5A is a schematic sectional view of manufacturing steps of the circuit board;

FIG. 5B is a schematic sectional view of the manufacturing steps of the circuit board;

FIG. 5C is a schematic sectional view of the manufacturing steps of the circuit board;

FIG. 5D is a schematic sectional view of the manufacturing steps of the circuit board;

FIG. 6 is a schematic exploded perspective view of a configuration of an image sensor unit;

FIG. 7 is a schematic external perspective view of the configuration of the image sensor unit;

FIG. 8 is a schematic sectional view of an internal structure of the image sensor unit taken along a surface perpendicular to a main-scan direction;

FIG. 9 is a schematic external perspective view of an example of a configuration of an image reading apparatus;

FIG. 10 is a schematic external perspective view of an example of a configuration of an image forming apparatus; and

FIG. 11 is a schematic perspective view, extracting an image forming portion arranged inside of a housing of the image forming apparatus.

### DETAILED DESCRIPTION OF THE PREFERRED EMBODIMENTS

Embodiments of the present invention will now be described in detail with reference to the drawings. The embodiments of the present invention illustrate a circuit board, an image sensor unit including the circuit board, and an image reading apparatus and an image forming apparatus provided with the image sensor unit. For the convenience of the description, a single board (board without elements) will be called a “printed board”, and a board including components and the like mounted on the printed board will be called a “circuit board”. In the drawings, three-dimensional directions will be illustrated by arrows of X, Y, and Z. An X direction is a main-scan direction of the image sensor unit including the circuit board. A Y direction is a sub-scan direction of the image sensor unit. A Z-axis direction is a vertical direction of the image sensor unit. In the embodiments of the present invention, light includes not only visible light, but also electromagnetic waves at wavelengths other than the visible light, such as infrared light and ultraviolet light.

### (Circuit Board)

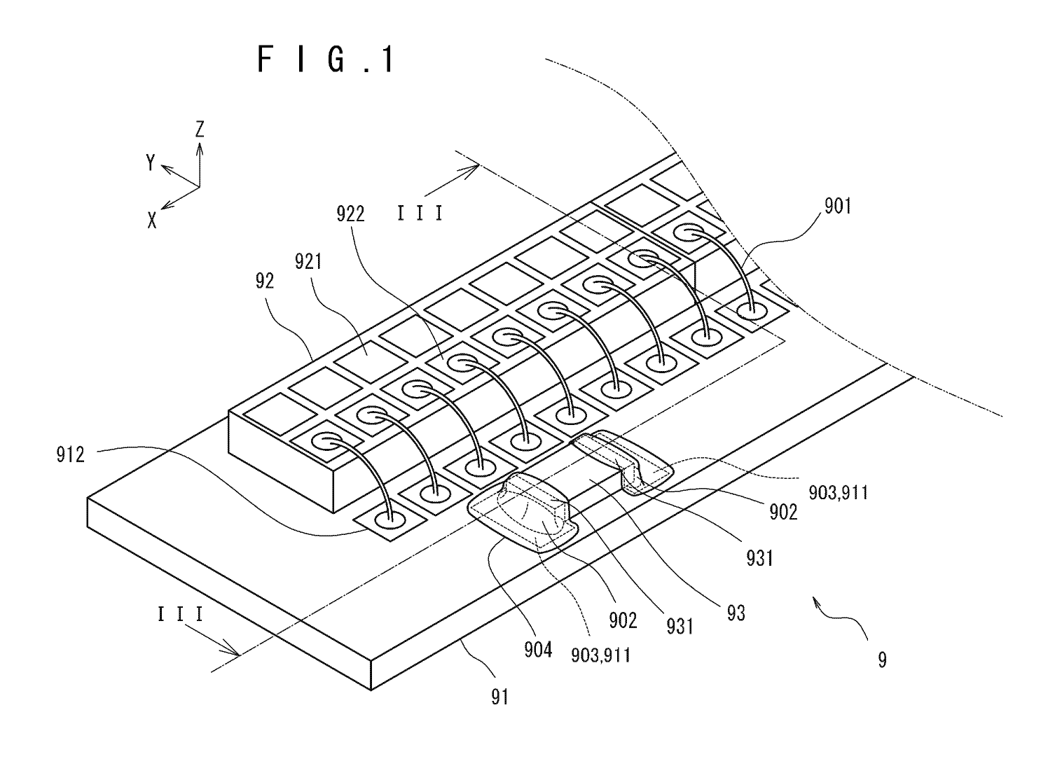

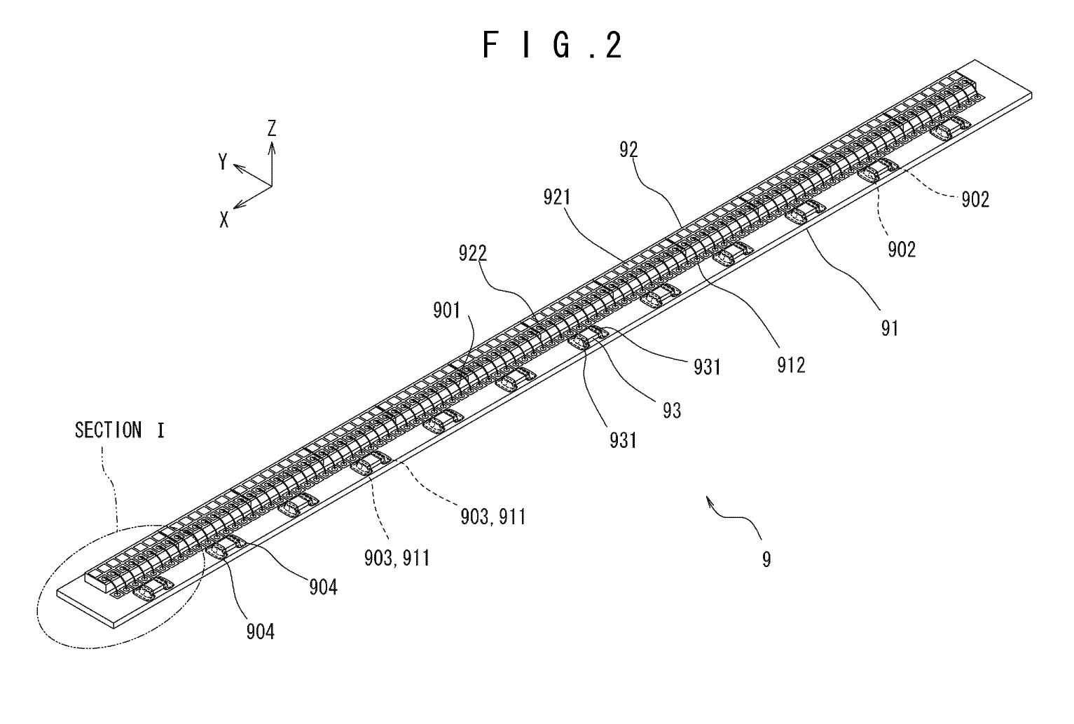

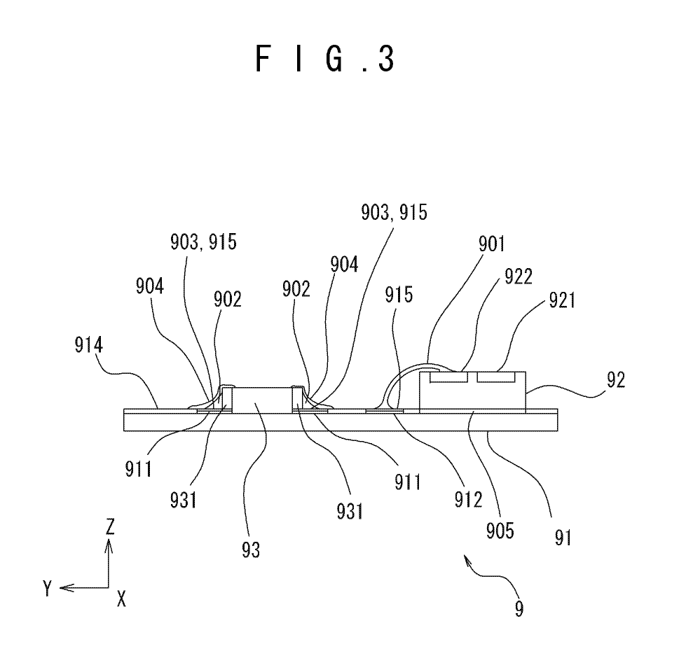

An example of a configuration of a circuit board will be described first with reference to FIGS. 1 to 3. FIG. 1 is a partially exploded view of the circuit board 9 and is an enlarged view of a section I of FIG. 2. FIG. 2 is a schematic external perspective view of the example of the configuration of the circuit board 9. FIG. 3 is a sectional arrow view of a line III-III of FIG. 1. As shown in FIGS. 1 to 3, the circuit board 9 includes: a printed board 91; first elements to be connected to the printed board 91 by wire bonding; and second elements to be mounted on the printed board 91 by using reflow soldering. The embodiments of the present invention illustrate image sensor ICs 92 as an example of the first elements. Surface-mount elements 93, such as chip resistors and chip capacitors, are illustrated as an example of the second elements.

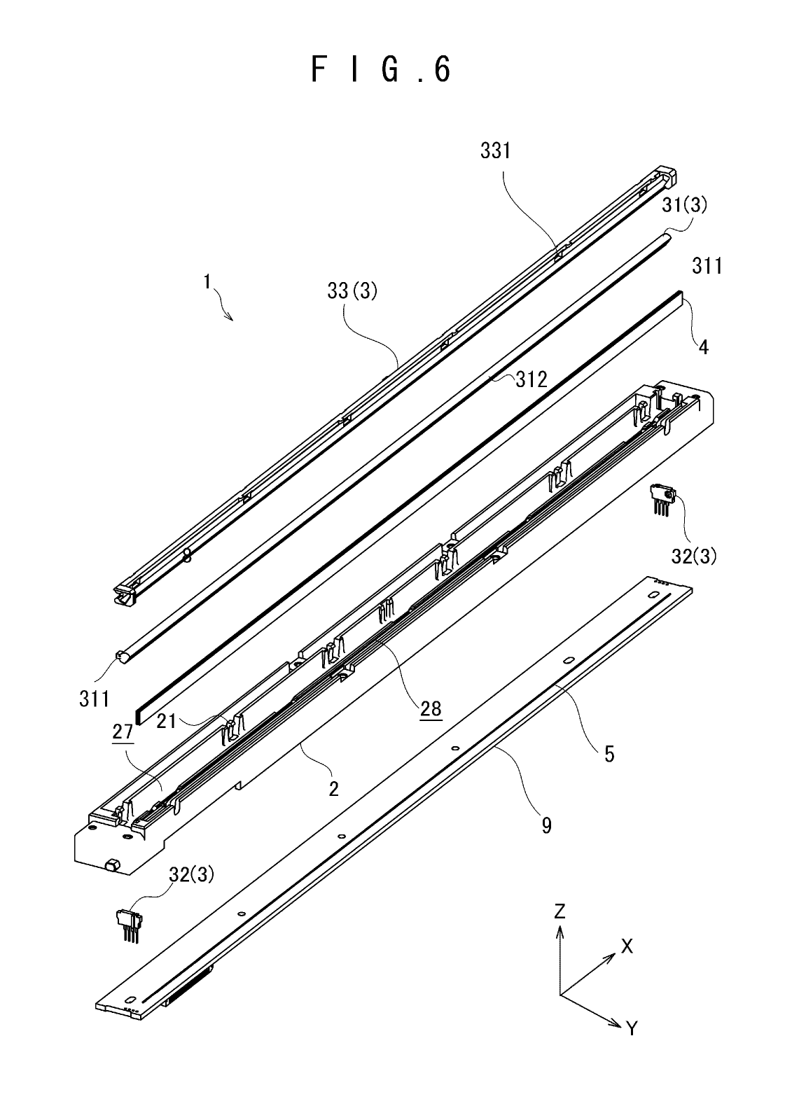

As shown in FIGS. 1 to 3, the circuit board 9 as a whole is formed in a rectangular shape that is long in the main-scan direction. A plurality of image sensor ICs 92 are arranged and mounted in the main-scan direction on an upper surface of the printed board 91. The plurality of image sensor ICs 92 form an image sensor IC array. The image sensor IC array serves as an image sensor 5 of the image sensor unit (see FIG. 6). The surface-mount elements 93 are mounted on the sides of the image sensor ICs 92. When the dimension in the sub-scan direction of the printed board 91 is reduced to downsize the circuit board 9, the distance between the image sensor ICs 92 and the surface-mount elements 93 in the sub-scan direction needs to be small.

The printed board 91 is formed in a rectangular shape that is long in the main-scan direction. The material of the printed board 91 is not particularly limited. The printed board 91 may be, for example, a ceramic board or a board made of a material softer than ceramic, such as an FR-4 board (glass fiber base epoxy resin). A plurality of board side pads (hereinafter, written as “SWB pads 912”) for wire bonding for electrical connection with the image sensor ICs 92 and a plurality of lands 911 for reflow soldering for mounting the surface-mount elements 93 are formed on the upper surface of the printed board (particularly, see FIG. 1). Gold plating films 915 are formed on the surfaces of the SWB pads 912 and the lands 911. In addition, a wiring pattern (not shown) is provided on the printed board 91. A solder resist film 914 may also be formed on the surface of the printed board 91 to cover the wiring pattern.

The image sensor IC 92 is bonded to the printed board 91 by using adhesive and electrically connected by using wire bonding. The image sensor IC 92 is a bare chip without a package and includes a plurality of photoelectric conversion elements 921 and a plurality of element side pads for wire bonding (hereinafter, written as “FWB pads 922”). The photoelectric conversion elements 921 convert incident light to electric signals. The FWB pads 922 are terminal pads for connecting bonding wires 901. The bonding wires 901 electrically connect the FWB pads 922 to the SWB pads 912 of the board (particularly, see FIGS. 1 and 3). The FWB pads 922 are formed of aluminum. The image sensor ICs 92 can output the electric signals converted by the photoelectric conversion elements 921 to the printed board 91 through the bonding wires 901 bonded to the FWB pads 922.

Reflow soldering is used to mount the surface-mount elements 93 on the upper surface of the printed board 91. Although a chip resistor or a chip capacitor is illustrated as an example of the surface-mount element 93, the type is not particularly limited. What kind of surface-mount elements 93 are mounted on the circuit board 9 is appropriately set according to the configuration and the like of the image sensor unit 1.

As particularly shown in FIG. 3, coating films 904 covering the surfaces of solders 902 connecting the electrode terminals 931 of the surface-mount elements 93 and the lands 911 are formed. The coating films 904 are provided to prevent diffusion of bromine remaining on the surfaces of the solders 902 or the printed board 91 in a curing process of bonding the image sensor ICs 92 to the printed board by a thermosetting adhesive. Therefore, the coating films 904 can be a material with heat resistance equal to or higher than the curing temperature in the curing process of bonding the image sensor ICs 92 to the printed board 91. If the coating films 904 include siloxane, the characteristics of the mounted elements may be affected and changed by the siloxane. Therefore, the coating films 904 can be a material not containing siloxane. An example of the material includes a resin material such as an epoxy resin. More specifically, when the printed board 91 is a glass substrate, such as FR-4, the coating films 904 can be model number CCN200DH-M or the like of Panasonic Factory Solutions Co., Ltd. When the printed board is a ceramic substrate, the coating films 904 can be model number CCN500D-8B or the like of Panasonic Factory Solutions Co., Ltd.

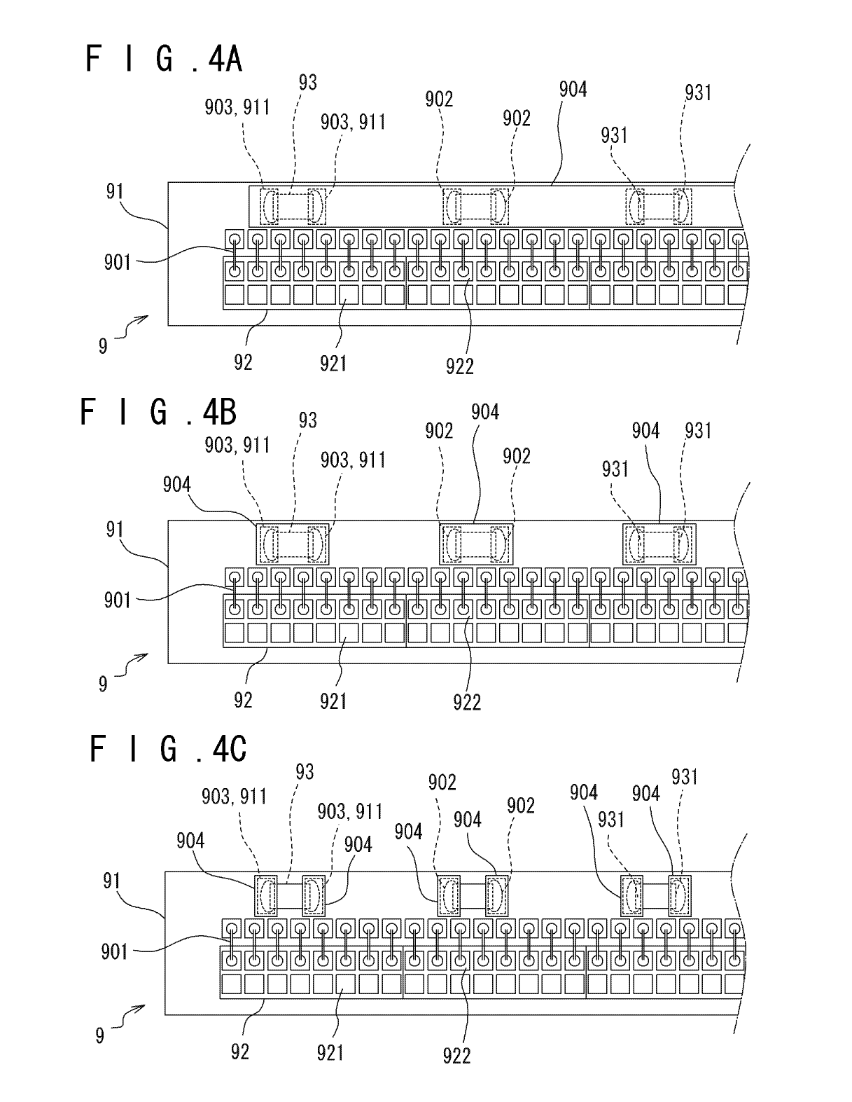

The coating films 904 are provided to prevent exposure of the solders 902 connecting the electrode terminals 931 of the surface-mount elements 93 and the lands 911 and exposure of areas 903 with flux included in the solders 902. An example of the areas 903 with flux includes an area where solder cream came into contact when the solder cream was applied. The coating films 904 are formed after the surface-mount elements 93 are mounted, before the image sensor ICs 92 are mounted (particularly, before the curing process). This prevents vaporization and diffusion of bromine remaining on the surfaces of the solders 902 and the printed boards 91 in the curing process. Examples of the range of the formation of the coating films 904 will be described with reference to FIGS. 4A to 4C. FIGS. 4A to 4C are diagrams showing examples of the range of the formation of the coating films 904. As shown in FIG. 4A, the coating film 904 may be formed in a band shape without interruption, throughout the whole length in the main-scan direction of the printed board 91. As shown in FIG. 4B, the coating films 904 may be provided on an element-to-element basis of the surface-mount elements 93. As shown in FIG. 4C, the coating films 904 may be provided only on the solders 902 and around the solders 902 (parts with flux) (i.e. the coating films 904 are provided on bonding parts of the solders 902). In short, it is only necessary that the coating films 904 cover both the solders 902, which connect the electrode terminals 931 of the surface-mount elements 93 with the lands 911, and the areas 903 with flux to prevent the exposure thereof.

When the difference between the coefficients of thermal expansion of the coating films 904 and the printed board 91 is large, the printed board 91 may be deformed if the size of the coating films 904 is large, and a kinetic load may be imposed on the image sensor ICs 92 and the surface-mount elements 93. Therefore, it is preferable to reduce the size of the coating films 904 in such a case. For example, it is preferable to apply the configuration shown in FIG. 4C. This configuration can prevent the deformation of the printed board 91 caused by the difference in the thermal expansion coefficient, even if the difference between the thermal expansion coefficients of the printed board 91 and the coating films 904 is large. This can prevent the kinetic load imposed on the image sensor ICs 92 and the surface-mount elements 93 mounted on the printed board 91.

### (Manufacturing Method of Circuit Board)

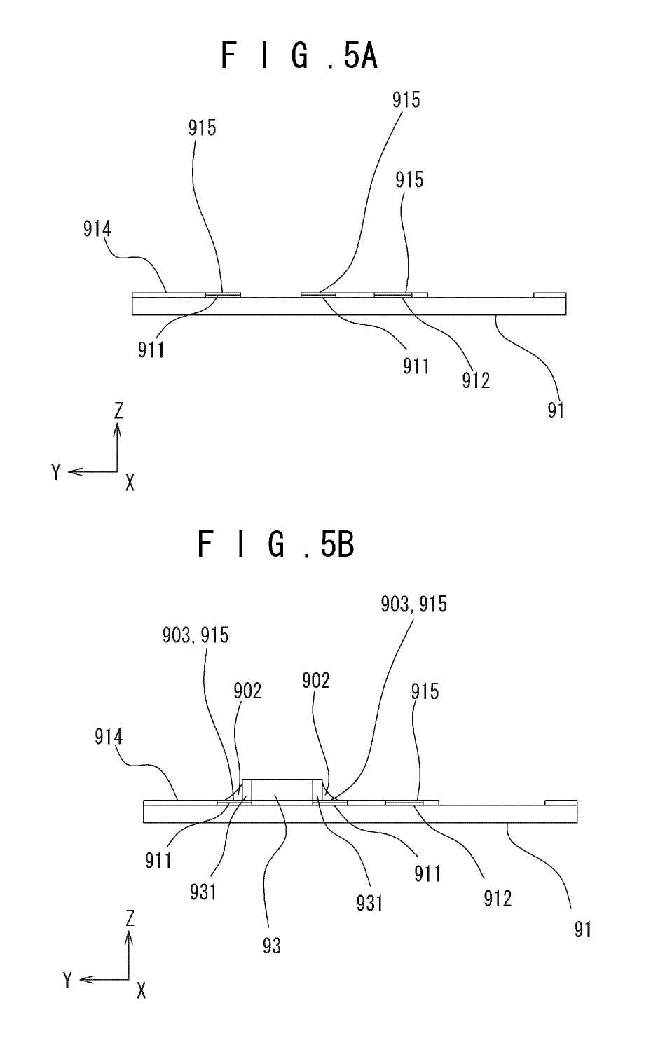

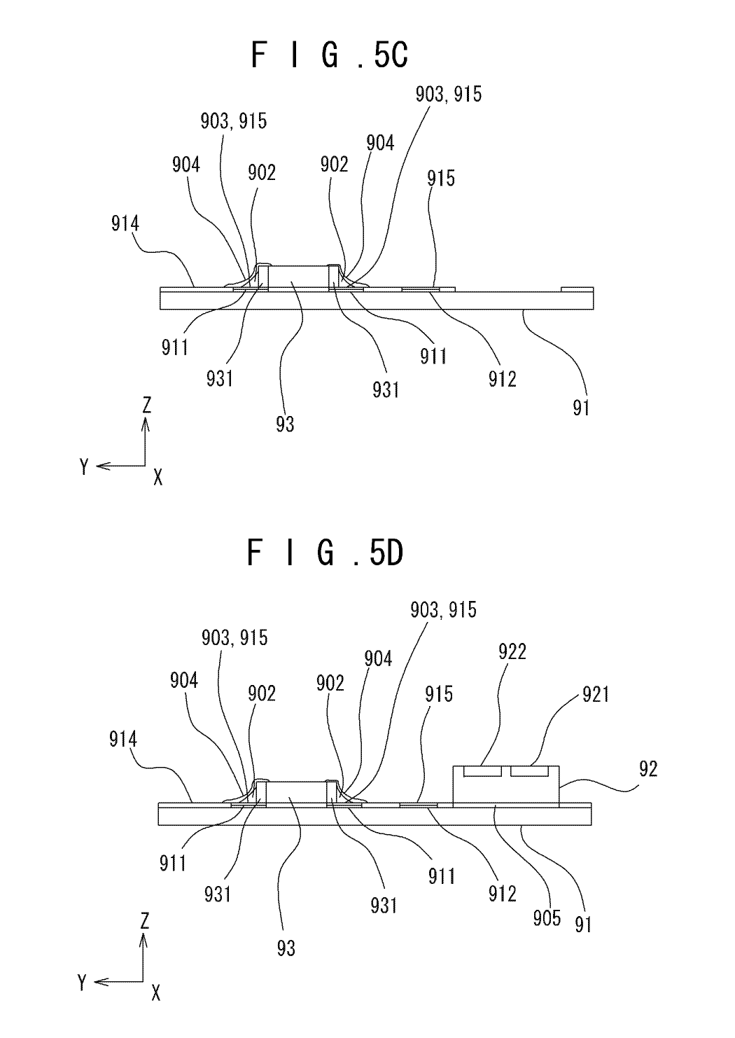

A manufacturing method of the circuit board 9 will be described with reference to FIGS. 5A to 5D. FIGS. 5A to 5D are schematic sectional views of steps of the manufacturing method of the circuit board 9. FIGS. 5A to 5D show the same sectional position as in FIG. 3.

FIG. 5A shows the printed board 91 in a state that the surface-mount elements 93 and the image sensor ICs 92 are not mounted. The SWB pads 912, the lands 911, and the wiring pattern are provided on the upper surface of the printed board 91. The solder resist film 914 that covers the wiring pattern is further formed on the upper surface of the printed board 91. The SWB pads 912 and the lands 911 are exposed without being covered with the solder resist film 914. The gold plating film 915 is formed on the surfaces of the SWB pads 912.

As shown in FIG. 5B, reflow soldering is used to mount the surface-mount elements 93. The method of reflow soldering can be a well-known method. The method will be simply described. A cream solder containing flux is applied to the surfaces of the lands 911. The surface-mount elements 93 are positioned and mounted on the upper surface of the printed board 91. The printed board 91 provided with the surface-mount elements 93 is heated by a reflow oven or the like, and the solders 902 are melted to bond the electrode terminals 931 of the surface-mount elements 93 to the lands 911. As a result, the surface-mount elements 93 are mounted on the printed board 91. Bromine is contained in the flux of the solders 902 used in this step to improve the solderability.

As shown in FIG. 5C, the coating films 904 that cover the solders 902 are formed. As shown in FIGS. 4A to 4C, the coating films 904 may be formed throughout the whole length in the main-scan direction of the printed board 91, may be formed on the element-to-element basis, or may be formed on the bonding parts. In short, it is only necessary that the coating films 904 cover the solders 902 connecting the electrode terminals 931 of the surface-mount element 93 and the lands 911 as well as the areas 903 with bromine to prevent the exposure thereof.

As shown in FIG. 5D, the image sensor ICs 92 are bonded to the upper surface of the printed board 91 by a thermosetting adhesive 905. Specifically, the following is performed. The thermosetting adhesive 905 is applied to the upper surface of the printed board 91, and the image sensor ICs 92 are placed on the mounting positions. A curing oven or the like is used to execute a curing process (heating process) to cure the adhesive 905. In this case, if the solders 902 connecting the electrode terminals 931 of the surface-mount elements 93 and the lands 911 are exposed, the bromine remaining on the surfaces of the solders 902 and the printed board 91 is vaporized and diffused. If the diffused bromine is attached to the SWB pads 912 of the printed board 91 and the FWB pads 922 of the image sensor ICs 92, the alloy of aluminum and gold corrodes after the wire bonding. However, the solders 902 are covered with the coating films 904 in the embodiments of the present invention. Therefore, the diffusion of bromine is prevented, and the bromine is not attached to the SWB pads 912 of the printed board 91 and the FWB pads 922 of the image sensor ICs 92.

Next, wire bonding is used to electrically connect the FWB pads 922 of the image sensor ICs 92 and the SWB pads 912 of the printed board 91 by the bonding wires 901 (see FIG. 3). In this way, the image sensor ICs 92 are bonded to the printed board 91 by the thermosetting adhesive 905 and electrically connected by wire bonding, as a result of which the image sensor ICs 92 are mounted on the printed board 91. The bonding wires 901 can be, for example, gold wires. When the FWB pads 922 are made of aluminum and the bonding wires 901 are gold wires, an alloy of aluminum and gold is formed at the bonding parts of the FWB pads 922 and the bonding wires 901.

Since the gold plating film 915 is formed on the surfaces of the SWB pads 912, the corrosion does not occur when the bonding wires 901 are gold wires. However, when bromine is attached to the surfaces of the SWB pads 912, the bromine attached to the SWB pads 912 may be moved and attached to the FWB pads 922 due to the movement of a bonding capillary at the wire bonding. Therefore, it is desirable to also prevent the attachment of bromine to the SWB pads 912.

The circuit board 9 is manufactured by the steps described above. The coating films 904 may be left or removed.

In this way, the coating films 904 are formed to cover the solders 902 connecting the electrode terminals 931 of the surface-mount elements 93 and the SWB pads 912 and to cover the areas 903 with flux, before the curing process of curing the thermosetting adhesive 905. This configuration can prevent the diffusion of bromine remaining on the surfaces of the solders 902 and the printed board 91 in the curing process. Therefore, bromine is not attached to the SWB pads 912 and the FWB pads 922, and the corrosion of the alloy of gold and aluminum formed at the bonding parts of the FWB pads 922 and the bonding wires 901 by bromine can be prevented.

Particularly, downsizing of the dimension in the sub-scan direction of the circuit board 9 is demanded to downsize the image sensor unit 1. Therefore, the distance between the FWB pads 922 of the image sensor ICs 92 and the lands 911 of the printed board 91 (particularly, distance in the sub-scan direction) needs to be reduced. When the bromine remaining on the surfaces of the solders 902 and the printed board is diffused in the curing process, the diffused bromine is easily attached to the SWB pads 912 and the FWB pads 922. With a decrease in the distance, the bromine is more easily attached to the SWB pads 912 and the FWB pads 922, and the amount of attached bromine increases. Therefore, according to the conventional configuration, the alloy of gold and aluminum formed at the bonding parts of the FWB pads 922 and the bonding wires 901 easily corrodes due to the bromine attached by the diffusion and the bromine moved from the SWB pads 912 caused by the movement of the capillary at the wire bonding.

The printed board 91, such as FR-4, cheaper than a ceramic board, is sometimes used to reduce the price of the circuit board 9. The rigidity of FR-4 is lower than the rigidity of ceramic, and the force applied to the FWB pads 922 of the image sensor ICs 92 and the bonding wires 901 is easily reduced in the wire bonding. Therefore, compared to a configuration in which the printed board 91 is a ceramic board, the strength of the bonding parts of the FWB pads 922 of the image sensor ICs 92 and the bonding wires 901 is reduced, and corrosion easily occurs due to bromine.

On the other hand, according to the embodiments of the present invention, the diffusion of bromine in the curing process can be prevented, and the attachment of bromine to the SWB pads 912 of the printed board 91 and the FWB pads 922 of the image sensor ICs 92 can be prevented. Particularly, bromine is not attached to the SWB pads 912 of the printed board 91 and the FWB pads 922 of the image sensor ICs 92 even if the distance between the lands 911 of the printed board 91 and the FWB pads 922 of the image sensor IC 92 is small. Therefore, the circuit board 9 can be downsized without reducing the reliability of the bonding parts of the FWB pads 922 of the image sensor ICs 92 and the bonding wires 901. Even if the printed board 91 with lower rigidity than that of ceramic, such as FR-4, is applied, there is no corrosion caused by bromine at the parts of connection with the bonding wires 901, and the reliability of the bonding parts is not reduced.

The coating films 904 may be provided on all solders 902 or may be provided on part of the solders 902. For example, only the solders 902 at positions within a predetermined distance from the FWB pads 922 of the image sensor ICs 92 may be covered with the coating films 904, and the other solders 902 may not be covered. The solders 902 at positions within the predetermined distance from the SWB pads 912 may also be covered with the coating films 904 to prevent the movement of bromine from the SWB pads 912 to the FWB pads 922. The “predetermined distance” here is a distance that the bromine diffused from the solders 902 in the curing process does not reach. The “predetermined distance” is appropriately set according to the type and the amount of the solders used, conditions of the curing process, and the like and is not particularly limited. In this way, bromine is not attached to the FWB pads 922 if the solders 902 at positions within the predetermined distance from the FWB pads 922 of the image sensor ICs 92 are covered with the coating films 904. Similarly, bromine is not attached to the SWB pads 912 if the solders 902 at positions within the predetermined distance from the SWB pads 912 are covered with the coating films 904.

### (Image Sensor Unit)

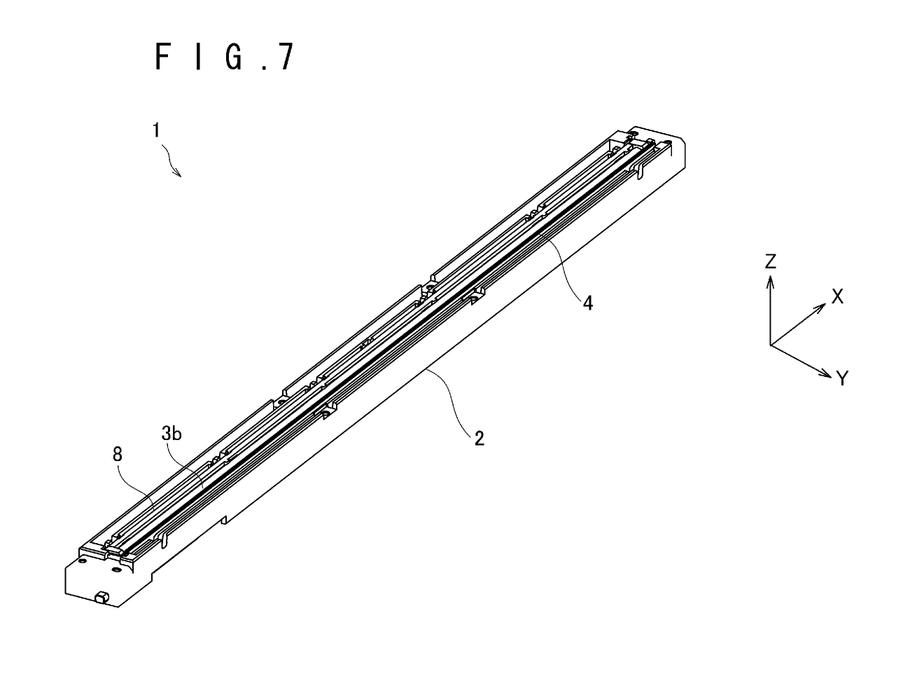

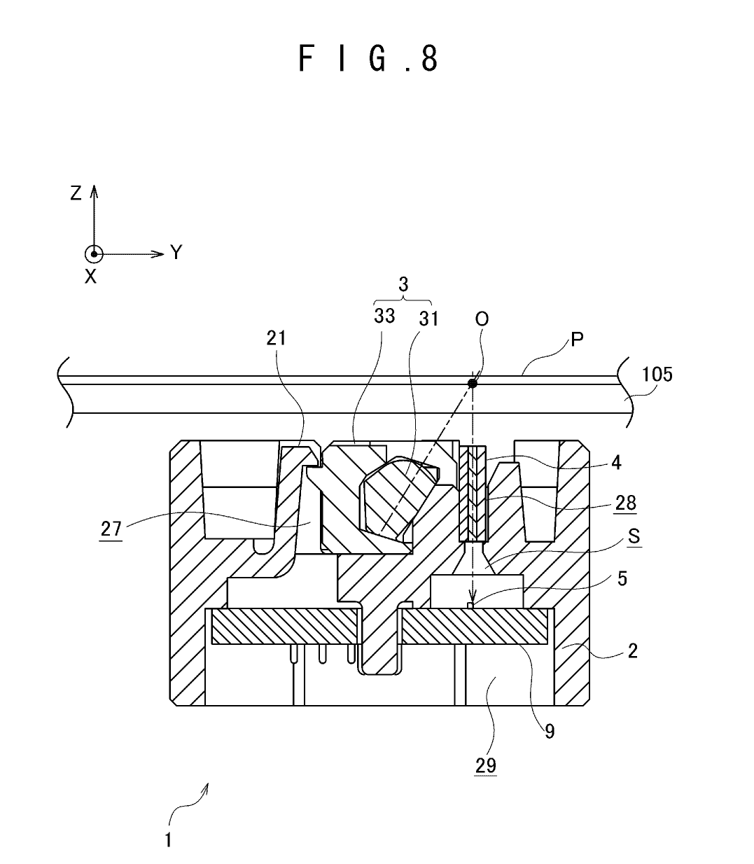

A configuration of the image sensor unit 1 will be described with reference to FIGS. 6 to 8. FIG. 6 is a schematic exploded perspective view of the configuration of the image sensor unit 1. FIG. 7 is a schematic external perspective view of the configuration of the image sensor unit 1. FIG. 8 is a schematic sectional view of an internal configuration of the image sensor unit 1 taken along a surface perpendicular to the main-scan direction. As shown in FIGS. 6 to 8, the image sensor unit 1 has a rectangular solid configuration that is long in the main-scan direction. The image sensor unit 1 includes a frame 2, an illumination apparatus 3, a light condenser 4, and the circuit board 9. The illumination apparatus 3 includes light sources 32, a light guide 31, and a light guide cover 33.

The circuit board 9 is provided with: the image sensor 5 including the plurality of image sensor ICs 92; and the light sources 32 and the surface-mount elements 93 (chip resistors and chip capacitors) that are elements different from the image sensor ICs 92. The coating films 904 covering the surfaces of the solders 902 are provided on the solders 902 connecting the surface-mount elements 93 among the elements different from the image sensor ICs 92. In this way, at least part (surface-mount elements 93) of the elements different from the image sensor ICs are mounted on the printed board 91 by reflow soldering. The coating films 904 for preventing the diffusion of bromine are provided on the surfaces of the solders 902 for mounting the surface-mount elements 93. The coating films 904 may be provided on the solders 902 of all of the surface-mount elements 93, or the coating films 904 may be provided on the solders 902 of part of the surface-mount elements 93. As described, the coating films 904 may be provided only on the solders 902 within the predetermined distance from the SWB pads 912 of the printed board 91 and the FWB pads 922 of the image sensor ICs 92.

The frame 2 is a housing of the image sensor unit and is a substantially rectangular solid member that is long in the main-scan direction. The light guide 31 provided with the light guide cover 33, the light condenser 4, and the circuit board 9 are housed and attached to the frame 2. The frame 2 is integrally formed of, for example, a light-blocking resin material colored in black. The resin material can be, for example, polycarbonate.

A light guide housing chamber 27, a light condenser housing chamber 28, and a circuit board housing chamber 29 (see FIG. 8) are formed on the frame 2. The light guide housing chamber 27 is an area that opens to the upper side, and the light guide 31 provided with the light guide cover 33 can be housed. The light condenser housing chamber 28 is an area that opens to the upper side, and the light condenser 4 can be housed. The circuit board housing chamber 29 is an area that opens to the lower side, and the circuit board 9 provided with the light sources 32 and the image sensor 5 can be housed. The frame 2 is provided with an opening S for linking the light condenser housing chamber 28 and the circuit board housing chamber 29, allowing the light to pass through. In addition, the frame 2 is provided with a holding claw 21 that positions and fixes the light guide cover 33 housed in the light guide housing chamber 27. The holding claw 21 is an elastically deformable structure protruding toward inside of the light guide housing chamber 27 and is integrated with the frame 2.

The light sources 32 of the illumination apparatus 3 include LEDs that emit light at wavelengths of red (R), green (G), blue (B), infrared light (Ir), and ultraviolet light (UV). The light guide 31 is an optical member that converts light emitted by the light sources 32 into a line light source. The light guide 31 of the illumination apparatus 3 is made of a transparent resin material, such as an acrylic resin, and is formed in a rod shape elongated in the main-scan direction. Light incident surfaces 311 that receive light from the light sources 32 are formed on end faces in the longitudinal direction (main-scan direction) of the light guide 31, and a light emission surface 312 that emits light toward an original P is formed on a side surface.

The light condenser 4 is an optical member that focuses reflected light from the original P on the surface of the image sensor 5. The light condenser 4 is, for example, a rod-lens array including a plurality of imaging elements (rod lenses) of an erect equal magnification imaging type linearly arranged in the main-scan direction. It is only necessary that the light condenser 4 includes linearly arranged imaging elements, and the configuration is not limited. For example, the light condenser 4 may include imaging elements arranged in a plurality of lines. The light condenser 4 can be an optical member with various well-known light condensing functions, such as various micro-lens arrays.

The image sensor 5 converts reflected light focused by the light condenser 4 to an electric signal. The image sensor 5 can be an image sensor IC array. The image sensor IC array includes the plurality of image sensor ICs 92 linearly mounted in the main-scan direction.

In addition, the image sensor unit 1 is provided with attachment portions for attachment to an image reading apparatus 10 (described later) or an image forming apparatus 50 (described later) and a connector for electrical connection to the image reading apparatus 10 or the image forming apparatus 50. The configurations of the attachment portions and the connector are not particularly limited. It is only necessary that the attachment portions allow attachment of the image sensor unit 1 to the image reading apparatus 10 or the image forming apparatus 50. It is only necessary that the connector can connect the image sensor unit 1 with the image reading apparatus 10 or the image forming apparatus 50, allowing transmission and reception of power and electric signals.

As shown in FIGS. 6 to 8, the light guide 31 provided with the light guide cover 33 is housed in the light guide housing chamber 27 of the frame 2. Consequently, the holding claw 21 arranged in the frame 2 is engaged with the light guide cover 33. As a result, the light guide 31 and the light guide cover 33 are housed and held in the light guide housing chamber 27. As shown in FIG. 8, the side surface of the light guide 31 is maintained in a state of contact with the inner surface of the light guide housing chamber 27 by urging force of an urging portion 331 of the light guide cover 33. As a result, the light guide 31 and the light guide cover 33 are positioned on the frame 2.

The light condenser 4 is housed in the light condenser housing chamber 28 of the frame 2. The circuit board 9 provided with the light sources 32 and the image sensor 5 is housed in the circuit board housing chamber 29.

When the light guide 31 is housed in the light guide housing chamber 27 and the circuit board 9 provided with the light sources 32 is housed in the circuit board housing chamber 29, the light sources face the light incident surfaces 311 formed at both ends of the light guide 31. Therefore, the light emitted by the light sources 32 is incident on the light incident surfaces 311 formed on both ends of the light guide 31.

To emit light to the original P, the light sources 32 sequentially turn on the light emitting elements of each color. The light emitted by the light sources 32 enters inside from the light incident surfaces 311 of the light guide 31 and propagates inside. The light is emitted toward a reading line O of the original P from the light emission surface 312 of the light guide 31. As shown in FIG. 8, an original supporting body 105 (described later) is arranged on the upper side of the image sensor unit 1 in a state that the image sensor unit 1 is incorporated into the image reading apparatus 10 or the image forming apparatus 50. The light condenser 4 collects the reflected light from the reading line O of the original P on the surface of the image sensor 5. The image sensor 5 converts an optical image formed by the light condenser 4 to an electric signal. The image sensor unit 1 performs the operation while moving in the sub-scan direction relative to the original P. As a result, the image sensor unit 1 can read the original P.

### (Image Reading Apparatus)

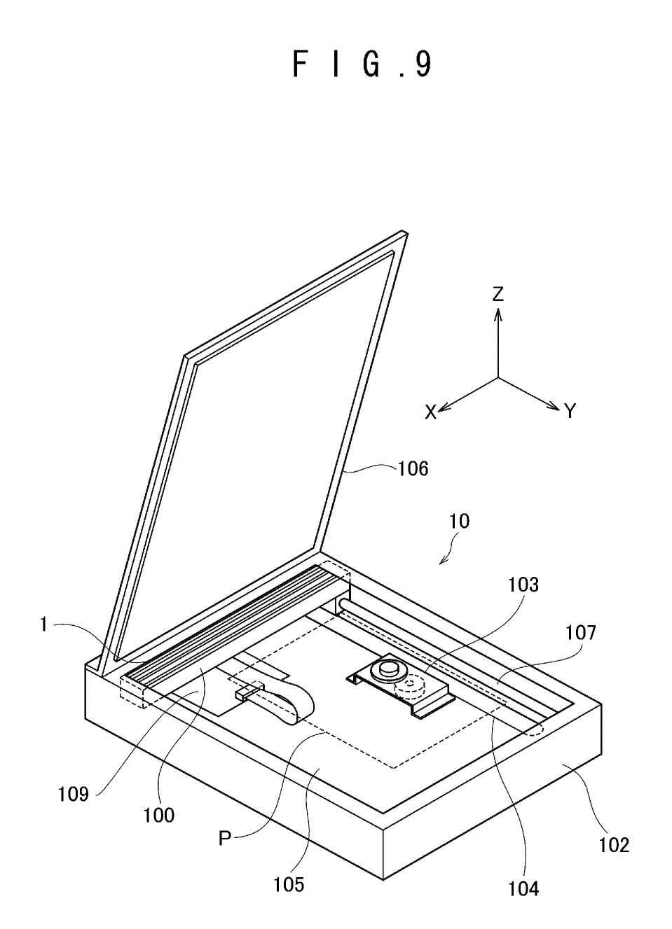

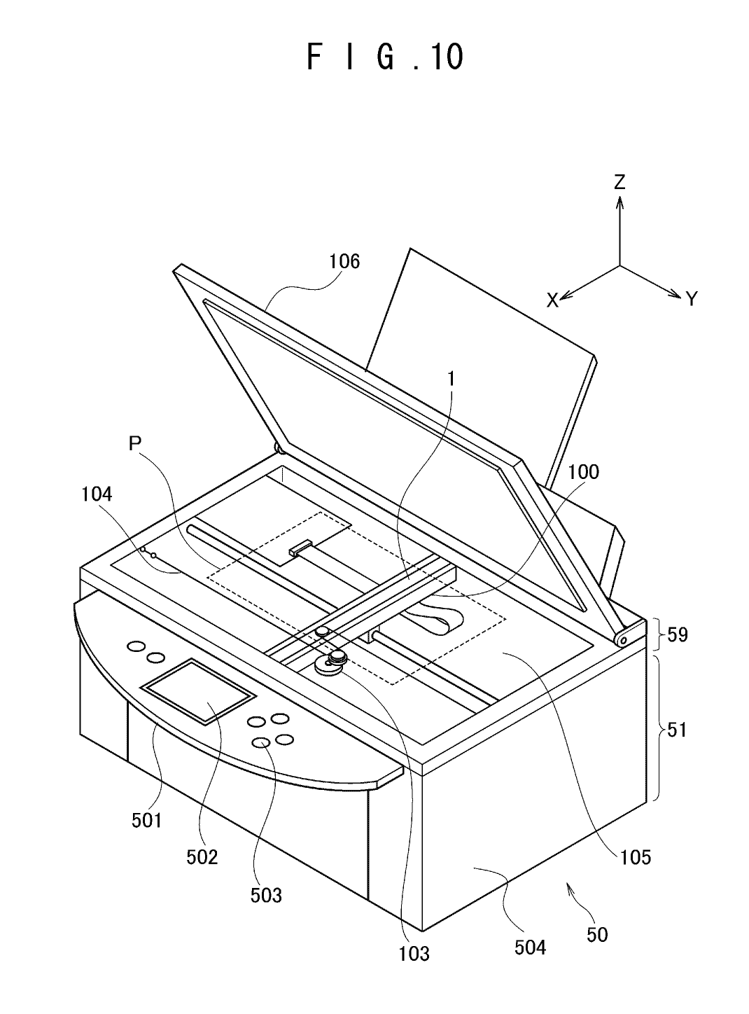

The image reading apparatus 10 as an embodiment of the present invention will be described with reference to FIG. 9. The image sensor unit 1 is applied as the image reading apparatus 10. FIG. 9 is a schematic external perspective view of an example of a configuration of the image reading apparatus 10. As shown in FIG. 9, the image reading apparatus 10 is a flat-bed type scanner. The image reading apparatus includes a housing 102, a unit table 100, and a unit table driving mechanism. The unit table 100 is a member on which the image sensor unit 1 can be mounted. The unit table driving mechanism is a mechanism for moving the unit table 100 provided with the image sensor unit 1 in the sub-scan direction. For example, the unit table driving mechanism includes: a drive motor 103; a wire 104 that transmits power of the drive motor 103 to the unit table 100; and a guide shaft 107 that guides the unit table 100. The configurations of the unit table 100 and the unit table driving mechanism are not particularly limited, and well-known configurations can be applied. In addition, an original supporting body 105 is arranged on the upper surface of the housing 102. The original supporting body 105 is, for example, a transparent glass plate. A pressure plate 106 is further attached to an end in the sub-scan direction of the housing 102, and the pressure plate 106 can be freely opened and closed by a hinge or the like. The pressure plate 106 has a function of holding the original P placed on the upper surface of the original supporting body 105.

The operation and usage of the image reading apparatus 10 are as follows. The user or the like places the original P facing downward on the upper surface of the original supporting body 105 and closes the pressure plate 106. In this state, the image reading apparatus 10 drives the drive motor 103 to move the wire 104 to move the image sensor unit 1 in the sub-scan direction. In this case, the guide shaft 107 guides the unit table 100. As a result, the image sensor unit 1 moves in the sub-scan direction relative to the original P. The image reading apparatus 10 reads each reading line of the image of the original P while moving the image sensor unit 1. A signal processing unit 109 applies image processing to the image read by the image sensor unit as necessary, and image data is stored. As a result, reading of the original P is completed.

The same configurations as in a well-known image reading apparatus can be applied to the parts not described in the image reading apparatus 10. Although the flat-bed type scanner has been described as the image reading apparatus 10, the image sensor unit 1 can also be applied to other types of image reading apparatuses, such as a sheet-feed type scanner.

### (Image Forming Apparatus)

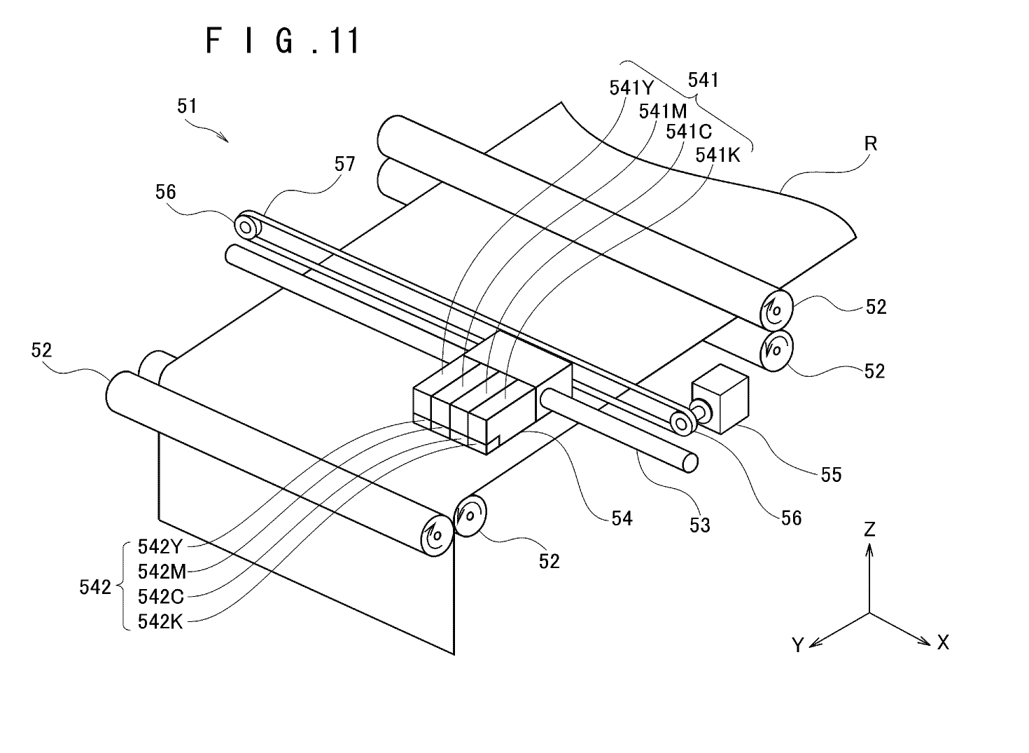

The image forming apparatus 50 as an embodiment of the present invention will be described with reference to FIGS. 10 and 11. The image sensor unit 1 is applied as the image forming apparatus 50. FIG. 10 is a schematic external perspective view of an example of a configuration of the image forming apparatus 50. FIG. 11 is a schematic perspective view, extracting an image forming portion 51 arranged inside of a housing of the image forming apparatus 50. As shown in FIGS. 10 and 11, the image forming apparatus 50 is a multifunction printer (MFP) of a flat-bed type scanner and an inkjet-type printer. The image forming apparatus 50 includes: an image reading portion 59 as image reading means for reading an image; and the image forming portion 51 as image forming means for forming an image. The image sensor unit 1 is incorporated into the image reading portion of the image forming apparatus 50. The same components as those of the image reading apparatus 10 can be applied to the image reading portion 59 of the image forming apparatus 50. Therefore, the same components as those of the image reading apparatus 10 are designated with the same reference numerals, and the description will not be repeated.

As shown in FIG. 10, the image forming apparatus includes an operation portion 501. The operation portion 501 includes: a display portion 502 that displays an operation menu, various messages, and the like; and various operation buttons 503 for operating the image forming apparatus 50.

As shown in FIG. 11, the image forming portion 51 is arranged inside of a housing 504 of the image forming apparatus 50. The image forming portion 51 includes conveyor rollers 52, a guide shaft 53, an inkjet cartridge 54, a motor 55, and a pair of timing pulleys 56. The conveyor rollers 52 are rotated by driving force of a driving source to convey printing paper R as a recording medium in the sub-scan direction. The guide shaft 53 is a rod-like member and is fixed to the housing 504 of the image forming apparatus 50 so that the axis line is parallel to the main-scan direction of the printing paper R. The inkjet cartridge 54 can slide over the guide shaft 53 to move back and forth in the main-scan direction of the printing paper R. The inkjet cartridge 54 includes, for example: ink tanks 541 with cyan C, magenta M, yellow Y, and black K inks (541C, 541M, 541Y, and 541K); and discharge heads 542 (542C, 542M, 542Y, and 542K) arranged on the ink tanks 541. One of the pair of timing pulleys 56 is attached to the rotating shaft of the motor 55. The pair of timing pulleys 56 are arranged at positions away from each other in the main-scan direction of the printing paper R. A timing belt 57 is wound around the pair of timing pulleys 56 in parallel with the pair of timing pulleys 56 and is coupled to the inkjet cartridge 54.

The image reading portion 59 of the image forming apparatus 50 converts the image read by the image sensor unit 1 to an electric signal in a form suitable for printing. Based on the electric signal converted by the image sensor unit 1 of the image reading portion 59, the image forming portion 51 of the image forming apparatus 50 drives the conveyor rollers 52, the motor 55, and the inkjet cartridge 54 to form the image on the printing paper R. The image forming portion 51 of the image forming apparatus 50 can also form an image based on an electric signal input from the outside. The configuration and operation of the image forming portion 51 of the image forming apparatus 50 can be the same configuration as various well-known printers. Therefore, the details will not be described.

Although various embodiments of the present invention have been described in detail, the embodiments are just specific examples for carrying out the present invention. The technical scope of the present invention is not limited to the above described embodiments. Various changes can be made in the present invention without departing from the scope of the present invention.

For example, although the circuit board incorporated into the image sensor unit is illustrated in the embodiments of the present invention, the application of the circuit board is not particularly limited. Similarly, the components and the like mounted on the circuit board are not limited to the image sensor ICs, the chip resistors, and the chip capacitors. In short, a circuit board including components and the like mounted by soldering and components and the like mounted by wire bonding can be applied regardless of the function or application. The image reading apparatus and the image forming apparatus according to the present invention are not limited to the multifunction printer. A copying machine and a facsimile, to which the image sensor unit according to the present invention is applied, are also included in the image reading apparatus or the image forming apparatus of the present invention.

The present invention is a technique suitable for a circuit board including components and the like mounted by soldering and components and the like mounted by using a thermosetting adhesive and connected by wire bonding. According to the present invention, diffusion of bromine remaining on solders can be prevented, and corrosion of bonding parts of wires and pads caused by bromine can be prevented.

According to the present invention, surfaces of solders can be covered with coating films to prevent diffusion of bromine from the solders in a curing process and prevent attachment of bromine to pads for wire bonding. Therefore, corrosion of bonding parts of wires and pads caused by bromine can be prevented.

What is claimed is:

1. A circuit board comprising:
a printed board comprising board side pads for wire bonding and soldering lands;
first elements mounted on the printed board by a thermosetting adhesive and comprising element side pads for wire bonding to be electrically connected to the board side pads by wire bonding; and
second elements to be mounted on the lands by soldering, wherein
the second elements and the lands are connected by solders including bromine-containing flux, and
coating films are formed on surfaces of the solders to prevent attachment of bromine to the board side pads and the element side pads.

2. The circuit board according to claim 1, wherein
the coating films are formed before the thermosetting adhesive is heated.

3. The circuit board according to claim 1, wherein
the coating films are provided on the solders at positions within a predetermined distance from the board side pads mounted on the printed board and the element side pads of the first elements.

4. The circuit board according to claim 1, wherein
the coating films are made of a resin material.

5. An image sensor unit comprising:
a printed board comprising board side pads for wire bonding and soldering lands;
image sensor ICs mounted on the printed board by a thermosetting adhesive and comprising element side pads for wire bonding to be electrically connected to the board side pads by wire bonding; and
elements other than the image sensor ICs mounted on the lands by soldering, wherein
at least part of the other elements and the lands are connected by solders including bromine-containing flux, and
coating films are formed on surfaces of the solders to prevent attachment of bromine to the board side pads and the element side pads.

6. An image reading apparatus that reads reflected light from an original while relatively moving an image sensor unit and the original,
the image sensor unit comprising:
a printed board comprising board side pads for wire bonding and soldering lands;
image sensor ICs mounted on the printed board by a thermosetting adhesive and comprising element side pads for wire bonding to be electrically connected to the board side pads by wire bonding; and
elements other than the image sensor ICs mounted on the lands by soldering, wherein
at least part of the other elements and the lands are connected by solders including bromine-containing flux, and
coating films are formed on surfaces of the solders to prevent attachment of bromine to the board side pads and the element side pads.

7. An image forming apparatus comprising:
image reading means for reading reflected light from an original while relatively moving an image sensor unit and the original; and
image forming means for forming an image in a recording medium,
the image sensor unit comprising:
a printed board comprising board side pads for wire bonding and soldering lands;
image sensor ICs mounted on the printed board by a thermosetting adhesive and comprising element side pads for wire bonding to be electrically connected to the board side pads by wire bonding; and
elements other than the image sensor ICs mounted on the lands by soldering, wherein
at least part of the other elements and the lands are connected by solders including bromine-containing flux, and
coating films are formed on surfaces of the solders to prevent attachment of bromine to the board side pads and the element side pads.
